(19) United States
(12) Patent Application Publication
(10) Pub. No.: US 2007/0283999 A1
(43) Pub. Date: Dec. 13, 2007

(54) SOLAR CELL GEOMEMBRANE ASSEMBLY

(76) Inventors: Barak Yekutiely, Kochav Yair (IL); David Yekutiely, Ramat HaSharon (IL)

Correspondence Address: David Klein;DEKEL PATENT LTD., Beit HaRof'im, Room 27, 18 Menuha VeNahala Street, REHOVOT, omitted

(21) Appl. No.: 11/746,691

(22) Filed: May 10, 2007

Related U.S. Application Data
(60) Provisional application No. 60/811,439, filed on Jun. 7, 2006.

(51) Int. Cl. H01L 31/00

(52) U.S. Cl. 136/259

(57) ABSTRACT

A solar cell geomembrane assembly including a solar cell integrated with a geomembrane, the geomembrane including a flexible floating cover material that floats partially submerged below a water surface.

### FIELD OF THE INVENTION

The present invention relates generally to solar cells, and particularly to solar cells integrated with a geomembrane as a source of solar generated electricity.

### BACKGROUND OF THE INVENTION

Geomembranes are liners or membranes that may be used to cover ponds, reservoirs, pools and the like. Geomembranes provide low cost, long-term lining and covering solutions and are available from various manufacturers, such as GSI (http://www.geo-synthetics.com/index.html). One brand from GSI is the Pondgard® EPDM Liner, which is a highly flexible liner with superior strength characteristics. The liner is safe for all fish and plants and is very UV stable. Another example is the blended Medium Density Polyethylene (MDPE) geomembrane which is low cost, long-lasting and has excellent elongation characteristics, which make it readily moldable around unusual shapes. The liner has a high carbon black content which provides extreme resistance to UV degradation.

### SUMMARY OF THE INVENTION

As described more in detail hereinbelow, the present invention seeks to integrate solar cells with a geomembrane to create a novel source of solar generated electricity. The solar membrane of the present invention uniquely uses solar cells that float on water (due to the geomembrane integration). The solar membrane may have a dual function: it acts as a conventional geomembrane (e.g., for controlling water evaporation and other uses), and it may be used to generate energy, such as for water related applications.

There is provided in accordance with an embodiment of the present invention a solar cell geomembrane assembly including a solar cell integrated with a geomembrane. The solar cell may be disposed on or attached to the geomembrane.

The geomembrane includes a flexible floating cover material that floats on a water surface or alternatively partially submerged below a water surface (in which case, water above the geomembrane functions as a magnifying glass to amplify suns rays that impinge upon the solar cell).

The solar cell may include a roll-print solar cell, wherein the solar cell is printed on a roll material. The roll material on which the solar cell is printed may serve as the geomembrane.

In accordance with an embodiment of the present invention, the solar cell is electrically connected to an electrical device. The electrical device may include at least one of a water pump, a water desalination unit, a water booster, a water treatment device, water delivery and management apparatus, and filtration system. The electrical device may include a power grid.

### BRIEF DESCRIPTION OF THE DRAWINGS

The present invention will be understood and appreciated more fully from the following detailed description taken in conjunction with the drawings in which:

FIG. 1 is a simplified illustration of a solar cell geomembrane assembly, constructed and operative in accordance with an embodiment of the present invention;

FIG. 2 is a simplified illustration of a solar cell geomembrane assembly, constructed and operative in accordance with another embodiment of the present invention; and

FIG. 3 is a simplified illustration of the solar cell geomembrane assembly with pivoting solar cells, constructed and operative in accordance with an embodiment of the present invention.

### DETAILED DESCRIPTION OF EMBODIMENTS

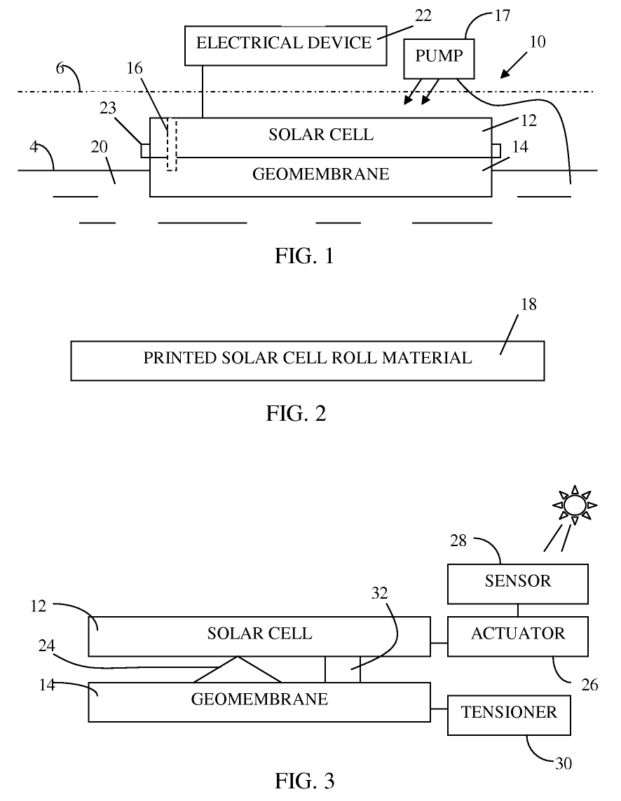

Reference is now made to FIG. 1, which illustrates a solar cell geomembrane assembly 10, constructed and operative in accordance with a non-limiting embodiment of the present invention.

The solar cell geomembrane assembly 10 includes one or more solar cells 12 (referred to simply as solar cell 12 and alternatively referred to as photovoltaic cell 12) integrated with (e.g., disposed on) a geomembrane 14. Geomembrane 14 is a flexible floating cover material suitable for floating in or on water surfaces. The solar cell geomembrane assembly 10 may float on a water surface (indicated by water level 4 in FIG. 1) or, in a preferred embodiment, floats partially submerged below the water surface (indicated by water level 6 shown in broken lines in FIG. 1). For example, the combination of solar cell 12 on geomembrane 14 may be used on an open water source such as an artificial lake with the solar material integrated in the lining. When partially submerged, the water actually functions as a magnifying glass to amplify the suns rays that impinge upon solar cell 12. Additionally or alternatively, a pump 17 may be provided that sprays water on the solar collecting surface of some or all of the photovoltaic cells. The water not only cools solar cell 12, but also can be used for cleaning solar cell 12 from dust/dirt.

Geomembrane 14 may include the Pondgard® EPDM Liner or the blended Medium Density Polyethylene (MDPE) geomembrane, both commercially available from GSI, or any other suitable liner, membrane or other flexible substrate (all the terms being used interchangeably throughout). Another suitable geomembrane flexible floating cover material is manufactured by Comanco Company, 4301 Sterling Commerce Drive, Plant City, Fla. 33566 (www.comanco.com). Geomembrane 14 may be inflatable.

The solar cell 12 may include a roll-print solar cell. Technology exists for printing solar cells on rolls. For example, NanoSolar of Palo Alto, Calif. (www.nanosolar.com) has developed proprietary technology that makes it possible to simply roll-print solar cells that require only 1/100th as thick an absorber as a silicon-wafer cell (yet deliver similar performance and durability).

A description of the NanoSolar process is found in PCT published application WO2006033858, corresponding to US Patent Application 20040782545, the disclosures of which are incorporated herein by reference, which describes photovoltaic devices, and more specifically, processing and annealing of absorber layers for photovoltaic devices. A typical Copper-Indium-Gallium-diSelenide (CIGS) solar cell structure includes a back electrode followed by a layer of molybdenum (Mo). A CIGS absorber layer is sandwiched between the Mo layer and a cadmium sulfide (CdS) junction partner layer. A transparent conductive oxide (TCO) such as zinc oxide (ZnOx) or tin oxide (SnO₂) formed on the CdS junction partner layer is typically used as a transparent electrode. US Patent Application 20040782545 describes fabrication of CIGS absorber layers on aluminum foil substrates. For example, a photovoltaic device includes an aluminum foil substrate, an optional base electrode and a nascent absorber including material containing elements of groups IB, IIIA, and (optionally) VIA.

Other non-limiting examples of photovoltaic cells that may be used to carry out the invention include, but are not limited to, advanced amorphous silicon photovoltaic modules, e.g., multi-junction amorphous silicon modules. For example, UNI-SOLAR brand silicon modules based on triple junction solar cells perform excellently under western European climatic conditions, with yields and performance ratios significantly higher than present crystalline silicon technologies. This effect is especially pronounced under low light conditions and under non-ideal orientations.

The triple junction technology provides unprecedented levels of efficiency and stability for amorphous silicon solar cells (stabilized aperture area cell efficiency of 7.0-7.5%). Each cell is composed of three semiconductor junctions stacked on top of each other. The bottom cell absorbs the red light, the middle cell the green/yellow light and the top cell absorbs the blue light. This spectrum splitting capability is one of the keys to higher efficiencies and higher energy output, especially at lower irradiation levels and under diffuse light. The cells are produced in a unique roll-to-roll vacuum deposition process on a continuous roll of stainless steel sheet, employing only a fraction of the materials and energy of the production of standard crystalline silicon solar cells. The result is a flexible, light weight solar cell. The solar cells are encapsulated in UV-stabilized and weather-resistant polymers. The polymer encapsulation includes EVA and fluoro-polymer TEFZEL (a DuPont film) on the front side. The resulting modules are exceptionally durable. By-pass diodes are connected across each cell, allowing the modules to produce power even when partially shaded.

The solar cell 12 may be embedded, tied, bonded (with an adhesive), fastened with one or more mechanical fasteners 16, joined or otherwise attached to the geomembrane 14. Some or all of solar cells 12 may be flexibly mounted to one another. Solar cell 12 is sealed to geomembrane 14 with a seal 23 at edges of solar cell 12. This is advantageous because without the seal 23, water and debris may accumulate between the solar cells and the geomembrane and degrade performance.

Another alternative is shown in FIG. 2. Instead of using the printed solar cell material on an existing cover material, in this embodiment a printed solar cell 18 is used as is or modified for use as covering material (assuming they meet the cover material/application requirements). Thus, with printed solar cell technology, the roll material on which the solar cell is printed serves as the geomembrane (collectively referred to as printed solar cell 18).

The combination of the solar cell on the geomembrane may provide many synergistic benefits, heretofore unattainable with prior art solar cells.

The combination of the solar cell 12 on the geomembrane 14 may be embodied as a new renewable energy generator that utilizes the existing area of a very large water reservoir 20 (or open sea) for numerous water related applications which are local to the water reservoir 20. For example, solar cell 12 may be electrically connected to an electrical device 22. In one embodiment, the electrical device 22 is a water-related electrical device, such as but not limited to, a water pump, a water desalination unit, a water booster, a water treatment device, water delivery and management apparatus, filtration system, etc., or any combination thereof. In another embodiment, the electrical device 22 is a general purpose electrical energy device, such as but not limited to, a power grid for home, industrial, lighting, etc., or any combination thereof.

Reference is now made to FIG. 3, which illustrates further alternative features of the solar cell geomembrane assembly 10. In accordance with an embodiment of the present invention, some or all of the solar cells 12 may be pivotally mounted on pivots 24. Additionally or alternatively, solar cell 12 may be mounted on bearings 32. One or more actuators 26 (e.g., inflatable membrane, cams, step motors, servomotors, etc.) may be in operative communication with the pivotally mounted solar cells 12 and may tilt the pivotally mounted solar cells 12 (or move them, the movement being facilitated by the bearings 32). A sensor 28 may be provided that senses an impinging angle of the sun. Sensor 28 may be in operative communication with the actuator(s) 26 for tilting the pivotally mounted solar cells 12 in accordance with the impinging angle of the sun sensed by sensor 28. In addition, the entire solar cell geomembrane assembly 10 may be rotated and controlled automatically to follow the angle of the sun's arc impinging thereupon by using automatic tensioners 30 (such as that described in U.S. Pat. No. 6,893,005, the disclosure of which is incorporated herein by reference) to further increase the annual power output. Actuator 26 as an inflatable membrane may control the buoyancy and level of the solar cells 12 for optimum operation, such as for achieving the best power under varying environmental and operational factors (e.g., solar direction/angle, wind, reservoir level, desired tension and stability for walking on the panels for maintenance, etc.).

The best tilt angle for any photovoltaic array is the one that produces the highest annual energy output for that particular location. The primary reference point is the latitude but other factors are involved as well. The arc of the sun varies with time of year so, typically, the shallow tilt angles produce more energy in the summer months while the steeper angles produce more energy in the winter months. The best, fixed angle is the compromise between the extremes that allows for the greatest delivered energy on an annualized basis. Tilt angle is especially important with crystalline PV technology, which is much more sensitive to the angle of the incident light as well as dust and dirt accumulations than amorphous silicon PV. Azimuth, or deviation from True South, has a similar impact on energy production as with tilt angle. Optimum performance is typically obtained with the tilted array aligned with True South. Deviations from True South skew the peak output curves in the direction of the deviation (East or West of True South). Generally, the steeper the tilt angle, the greater the effect that the deviation from True South has on the annual energy output.

It will be appreciated by persons skilled in the art that the present invention is not limited by what has been particularly shown and described hereinabove. Rather the scope of the present invention includes both combinations and subcombinations of the features described hereinabove as well as modifications and variations thereof which would occur to a person of skill in the art upon reading the foregoing description and which are not in the prior art.

What is claimed is:

1. A solar cell geomembrane assembly comprising:
a solar cell integrated with a geomembrane, said geomembrane comprising a flexible floating cover material that floats partially submerged below a water surface.

2. The solar cell geomembrane assembly according to claim 1, wherein said solar cell is disposed on said geomembrane.

3. The solar cell geomembrane assembly according to claim 1, wherein said solar cell is sealed to said geomembrane with a seal at edges of said solar cell.

4. The solar cell geomembrane assembly according to claim 1, wherein said solar cell comprises a roll-print solar cell, wherein the solar cell is printed on a roll material.

5. The solar cell geomembrane assembly according to claim 4, wherein the roll material on which the solar cell is printed serves as the geomembrane.

6. The solar cell geomembrane assembly according to claim 1, wherein said solar cell is fastened with a mechanical fastener to said geomembrane.

7. The solar cell geomembrane assembly according to claim 1, wherein said solar cell is electrically connected to an electrical device.

8. The solar cell geomembrane assembly according to claim 1, wherein said solar cell is pivotally mounted on a pivot.

9. The solar cell geomembrane assembly according to claim 8, further comprising a sensor that senses an impinging angle of sun on said solar cell, said sensor being in operative communication with an actuator for tilting said solar cell about said pivot.

10. The solar cell geomembrane assembly according to claim 1, wherein said entire solar cell geomembrane assembly is rotated and controlled automatically to follow an angle of sun impinging thereupon.

11. The solar cell geomembrane assembly according to claim 1, wherein water above said geomembrane functions as a magnifying glass to amplify sun rays that impinge upon said solar cell.

12. The solar cell geomembrane assembly according to claim 1, wherein said solar cell is mounted on bearings.

13. The solar cell geomembrane assembly according to claim 1, further comprising a pump arranged to spray water on said solar cell.

14. The solar cell geomembrane assembly according to claim 9, wherein said actuator comprises an inflatable membrane that controls buoyancy of said solar cell.
